(19) United States
(12) Patent Application Publication
(10) Pub. No.: US 2024/0421054 A1
(43) Pub. Date: Dec. 19, 2024

(54) SEMICONDUCTOR PACKAGE

(71) Applicant: Samsung Electronics Co., Ltd., Suwon-si (KR)

(72) Inventors: Seongho Shin, Suwon-si (KR); Donguk Kim, Suwon-si (KR)

(21) Appl. No.: 18/617,964

(22) Filed: Mar. 27, 2024

(30) Foreign Application Priority Data
Jun. 13, 2023 (KR) 10-2023-0075623
Aug. 28, 2023 (KR) 10-2023-0113046

(51) Int. Cl. H01L 23/498; H01L 23/00

(52) U.S. Cl. CPC H01L 23/49816; H01L 23/49894; H01L 24/16; H01L 24/81; H01L 24/13; H01L 2224/13111; H01L 2224/13116; H01L 2224/13139; H01L 2224/13144; H01L 2224/13147; H01L 2224/13157; H01L 2224/13164; H01L 2224/16227; H01L 2224/8138; H01L 2224/81424; H01L 2224/81439; H01L 2224/81447; H01L 2224/81466; H01L 2224/81471; H01L 2224/8148; H01L 2224/81481

(57) ABSTRACT

A semiconductor package according to an embodiment may include a printed circuit board that includes a first pad portion, a semiconductor chip that is mounted on the printed circuit board and includes a second pad portion, a coupling part that is between the first pad portion and the second pad portion, and a spacer that is between the coupling part and the first pad portion. The first pad portion and the second pad portion may be electrically coupled to each other through the coupling part and the spacer.

### CROSS-REFERENCE TO RELATED APPLICATION

This application claims priority to Korean Patent Application No. 10-2023-0075623 filed in the Korean Intellectual Property Office on Jun. 13, 2023, and Korean Patent Application No. 10-2023-0113046 filed in the Korean Intellectual Property Office on Aug. 28, 2023, the entire contents of which are incorporated herein by reference.

### FIELD

The present disclosure relates to a semiconductor package.

### BACKGROUND

Semiconductor devices may be mounted on printed circuit boards (PCBs). As the sizes of semiconductor devices that are mounted on printed circuit boards are reduced, the parasitic capacitance between circuit wiring of the printed circuit boards and the semiconductor devices may increase. The parasitic capacitance may have an effect of interfering with high-speed operations of the semiconductor devices.

### SUMMARY

The present disclosure provides a semiconductor package capable of reducing the effect of parasitic capacitance between circuit wiring of a circuit board and semiconductor devices. However, the effects of the embodiments are not limited to the above, and can be variously expanded without departing from the scope of the embodiments.

A semiconductor package according to an embodiment may include a printed circuit board that includes a first pad portion, a semiconductor chip that is mounted on the printed circuit board and includes a second pad portion, a coupling part that is between the first pad portion and the second pad portion, and a spacer that is disposed between the coupling part and the first pad portion. The first pad portion and the second pad portion may be electrically coupled to each other through the coupling part and the spacer.

A semiconductor package according to an embodiment may include a printed circuit board including a first pad portion and a spacer of a first conductive material thereon, where the spacer protrudes away from the printed circuit board and has a first thickness; a semiconductor chip on the printed circuit board and including a second pad portion; and a coupling part having a second thickness between the conductive spacer and the second pad portion. The coupling part includes a second conductive material that is different than the first conductive material. The spacer and the coupling part electrically couple the first pad portion and the second pad portion. A combined thickness of the first thickness of the spacer and the second thickness of the coupling part separates the semiconductor chip from the printed circuit board by a distance that is more than 1 time but less than 3 times greater than the second thickness of the coupling part.

According to embodiments, it is possible to provide a semiconductor package capable of reducing the effect of parasitic capacitance between circuit wiring of a circuit board and semiconductor devices. However, the effects of the embodiments are not limited to the above-described effects, and it will be understood that they can be variously expanded without departing from the scope of this disclosure.

### BRIEF DESCRIPTION OF THE DRAWINGS

FIG. 1 is a plan view of a semiconductor package according to an embodiment.

FIG. 2 is a cross-sectional view taken along line I-I′ in FIG. 1.

FIG. 3 is an enlarged view of a portion of FIG. 2.

FIG. 4 is a plan view of a semiconductor package according to another embodiment.

FIG. 5 is a cross-sectional view taken along line I-I′ in FIG. 4.

FIG. 6 is an enlarged view of a portion of FIG. 5.

FIG. 7 is a graph illustrating the result of an experimental example according to an embodiment.

FIG. 8 is a graph illustrating the result of another experimental example according to an embodiment.

### DETAILED DESCRIPTION OF EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the scope of the present disclosure.

In order to clearly describe the present disclosure, parts or portions that are well-understood or irrelevant to the description are omitted, and identical or similar constituent elements throughout the specification are denoted by the same reference numerals.

Further, the accompanying drawings are provided only in order to allow embodiments disclosed in the present specification to be easily understood and are not to be interpreted as limiting the scope of embodiments disclosed in the present specification, and it is to be understood that the present disclosure includes all modifications, equivalents, and substitutions without departing from the scope of the present disclosure.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity.

It will be understood that when an element such as a layer, film, region, area, or substrate is referred to as being “on” or “above” another element, it may be directly on the other element or intervening elements may also be present. In contrast, when an element is referred to as being “directly on” or “in direct contact with” or “directly coupled to” or “directly connected to” another element, there are no intervening elements present.

Further, in the specification, the word “on” or “above” can mean on or below the object portion, and does not necessarily mean disposed on the upper side of the object portion based on a gravitational direction. That is, spatially relative terms such as ‘on,’ ‘above,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

The terms “first,” “second,” etc., may be used herein merely to distinguish one component, layer, direction, etc. from another. In addition, unless explicitly described to the contrary, the word “comprise” and variations such as “comprises” or “comprising” will be understood to imply the inclusion of stated elements but not the exclusion of any other elements. In contrast, the term “consists of” may imply the exclusion of any elements beyond those specifically listed. The term “and/or” includes any and all combinations of one or more of the associated listed items.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Furthermore, throughout the specification, “connected” or “coupled” does not only mean when two or more elements are directly connected or coupled, but also when two or more elements are indirectly connected or coupled through other elements, and when they are physically or electrically connected or coupled, and further, it may be referred to by different names depending on a position or function, and may also be referred to as a case in which respective parts that are substantially integrated are linked to each other.

Hereinafter, various embodiments and variations will be described in detail with reference to the drawings.

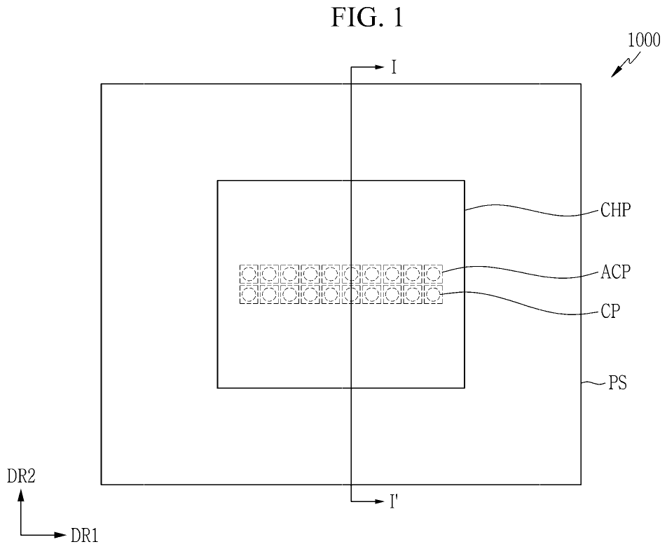

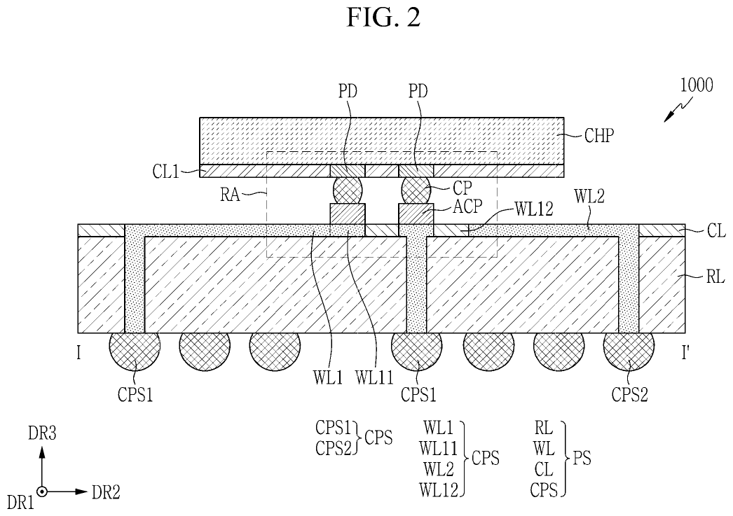

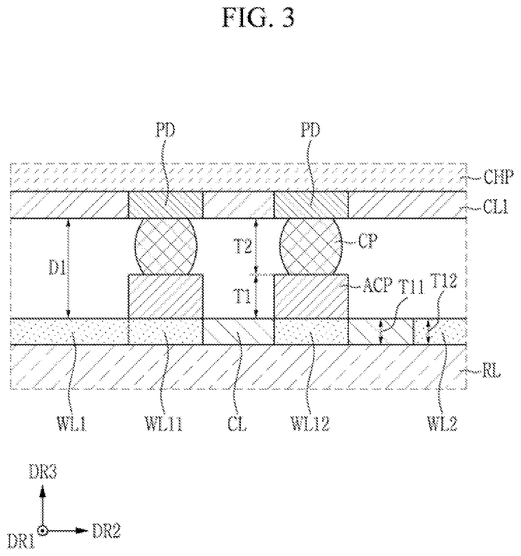

With reference to FIG. 1 to FIG. 3, a semiconductor package according to an embodiment will be described. FIG. 1 is a plan view of a semiconductor package according to an embodiment, and FIG. 2 is a cross-sectional view taken along line I-I′ in FIG. 1, and FIG. 3 is an enlarged view of a portion of FIG. 2.

Referring to FIG. 1, a semiconductor package 1000 according to an embodiment may include a printed circuit board PS, and a semiconductor chip CHP mounted on the printed circuit board PS.

Between the printed circuit board PS and the semiconductor chip CHP, a plurality of coupling parts CP and a plurality of spacers ACP. The semiconductor chip CHP may be physically and electrically coupled to the printed circuit board PS through the plurality of coupling parts CP and the plurality of spacers ACP. As such, the coupling parts CP and the spacers ACP include conductive materials. In some embodiments, the spacers ACP may include a different conductive material than the coupling parts CP.

The plurality of spacers ACP may overlap the plurality of coupling parts CP, respectively, in plan view. Components or layers described with reference to “overlap” in a particular direction or view may be at least partially obstructed by one another when viewed along a line extending in the particular direction or in a plane perpendicular to the particular direction.

The printed circuit board PS and the semiconductor chip CHP may extend along a first direction DR1 and a second direction DR2 different from each other, and the plurality of coupling parts CP may be disposed adjacent to the center portion or central region of the semiconductor chip CHP in the second direction DR2, and the plurality of coupling parts CP may be disposed in a line or aligned along the first direction DR1. The first direction DR1 and the second direction DR2 may be referred to as horizontal or lateral directions.

The plurality of coupling parts CP is disposed in a line adjacent to the center portion or central region of the semiconductor chip CHP, so that main components of the semiconductor chip CHP may be disposed on both or opposing sides of the semiconductor chip CHP in the second direction DR2 to reduce the distances between the main components of the semiconductor chip CHP and the plurality of coupling parts CP as compared to the case where the plurality of coupling parts CP is disposed at one end of the semiconductor chip CHP.

Therefore, even if the size of the semiconductor chip CHP increases, it is possible to reduce the distances of or between the semiconductor chip CHP (or components thereof) and the plurality of coupling parts CP, thereby reducing or preventing delay of signals of the semiconductor chip CHP, etc.

Referring to FIG. 1 and FIG. 2 together, the printed circuit board PS may include an insulating layer RL, a plurality of wiring layers WL that is disposed on the insulating layer RL, a passivation layer CL that covers the insulating layer RL and the plurality of wiring layers WL of the printed circuit board PS to protect them, and a plurality of connection parts CPS that is coupled to the plurality of wiring layers WL.

The insulating layer RL may be formed of a thermosetting resin such as an epoxy resin, a thermoplastic resin such as polyimide, or a thermosetting resin or a thermoplastic resin containing a reinforcement material such as glass fiber or an inorganic filler, for example, prepreg, and may also contain a thermosetting resin and/or a photo-curable resin, and so on; however, the embodiment is not limited thereto.

The plurality of wiring layers WL may include a first wiring layer WL1 and a second wiring layer WL2, and the first wiring layer WL1 may include a first pad portion WL11, and the second wiring layer WL2 may not be coupled to the semiconductor chip CHP. The plurality of wiring layers WL may include a second pad portion WL12 which are not coupled to the first wiring layer WL1 and the second wiring layer WL2. The first pad portion WL11 may be an end portion of the first wiring layer WL1. However, the embodiment is not limited thereto, and the plurality of wiring layers WL may include more wiring layers besides or in addition to the first wiring layer WL1 and the second wiring layer WL2.

The plurality of wiring layers WL may contain a metal, such as aluminum (Al), silver (Ag), copper (Cu), molybdenum (Mo), chromium (Cr), tantalum (Ta), titanium (Ti), etc., an alloy thereof, etc. However, the plurality of wiring layers WL may contain various other metals or conductors.

The passivation layer CL may cover the insulating layer RL and the plurality of wiring layers WL of the printed circuit board PS to protect them. The passivation layer CL may not cover at least a portion of the plurality of wiring layers WL. More generally, the terms “surrounding” or “covering” or “filling” as may be used herein may not require completely surrounding or covering or filling the described elements or layers, but may, for example, refer to partially surrounding or covering or filling the described elements or layers, for example, with voids or other spaces throughout. For example, the first pad portion WL11 and the second pad portion WL12 may not be covered or may be exposed by the passivation layer CL; however, the embodiment is not limited thereto. The term “exposed” may be used to describe relationships between elements and/or certain intermediate processes in fabricating a completed semiconductor device, but may not necessarily require exposure of the particular region, layer, structure or other element in the context of the completed device.

The passivation layer CL may contain a resin, and may be a solder resist. However, the embodiment is not limited thereto.

Along a third direction DR3 perpendicular to the first direction DR1 and the second direction DR2, the spacers ACP may be disposed on the first pad portion WL11 and the second pad portion WL12, respectively, and the coupling parts CP may be disposed on the spacers ACP.

The third direction DR3 may be a direction substantially perpendicular to the front surfaces of the printed circuit board PS and the semiconductor chip CHP. The third direction DR3 may be referred to as a vertical direction that is substantially perpendicular to the horizontal or lateral first direction DR1 and second direction DR2.

The coupling parts CP may contain at least one of lead (Pb), copper (Cu), tin (Sn), gold (Au), silver (Ag), palladium (Pd), and cobalt (Co). The coupling parts CP may include solder balls, solder bumps, stud bumps, pillars, conductive layers, conductive pastes, and wire bonding. However, the embodiment is not limited thereto.

The plurality of spacers ACP may have conductivity. That is, the spacers ACP may include a conductive material, and may also be referred to as conductive spacers ACP. The plurality of spacers ACP may contain the same conductive material as that of the plurality of wiring layers WL. The plurality of spacers ACP may be or may be part of the same layer as that of the plurality of wiring layers WL. For example, when the plurality of wiring layers WL is formed of a metal layer, the plurality of spacers ACP that are part of the same layer as that of the first wiring layer WL1 and the second wiring layer WL2 may be formed (e.g., integrally) so as to protrude upward in the third direction DR3 from the first wiring layer WL1 and the second wiring layer WL2, by forming portions of the metal layer at the formation positions of the first pad portion WL11 and the second pad portion WL12 thicker. That is, the spacers ACP and the respective pad portions WL11, WL12 may be unitary in some embodiments.

The coupling parts CP may be coupled to pad portions PD of the semiconductor chip CHP. As used herein, elements described as “coupled” or “connected to” one another may be physically and/or electrically coupled or connected to one another. The pad portions PD of the semiconductor chip CHP may not be covered by a first passivation layer CL1 so as to be exposed thereby, and may be coupled to the coupling parts CP. The first passivation layer CL1 may cover the semiconductor chip CHP to protect it. The first passivation layer CL1 may contain a resin, and may be a solder resist. However, the embodiment is not limited thereto.

The plurality of connection parts CPS may include first connection parts CPS1 that are coupled to the first pad portion WL11 and the second pad portion WL12, and a second connection part CPS2 that is coupled to the second wiring layer WL2.

Through the plurality of connection parts CPS, the printed circuit board PS may be coupled to an external device.

Referring to FIG. 3 together with FIG. 1 and FIG. 2, the plurality of coupling parts CP and the plurality of spacers ACP may be disposed between the printed circuit board PS and the semiconductor chip CHP.

The plurality of coupling parts CP and the plurality of spacers ACP may be disposed on the first pad portion WL11 and the second pad portion WL12, and the plurality of spacers ACP may protrude from the first pad portion WL11 and the second pad portion WL12 above the passivation layer CL, that is, may extend beyond the passivation layer CL in a direction away from the printed circuit board PS.

The thickness T11 of the first pad portion WL11 and the second pad portion WL12 may be substantially equal to or smaller than the thickness T12 of the passivation layer CL.

The first thickness T1 of the plurality of spacers ACP may be about 0.2 times to 1.7 times the second thickness T2 of the plurality of coupling parts CP, and in some embodiments may be about 0.4 times to about 1.5 times the second thickness T2. For example, the second thickness T2 of the plurality of coupling parts CP may be about 40 μm to about 50 μm, and the first thickness T1 of the plurality of spacers ACP may be about 20 μm to about 75 μm; however, the embodiment is not limited thereto.

As described above, the plurality of spacers ACP may have conductivity. The plurality of spacers ACP may contain the same conductive material as that of the plurality of wiring layers WL. The plurality of spacers ACP may be portions of the same layer as that of the plurality of wiring layers WL.

Between the first pad portion WL11 and the second pad portion WL12 of the printed circuit board PS and the plurality of pad portions PD of the semiconductor chip CHP, the plurality of spacers ACP may be further disposed besides or in addition to the plurality of coupling parts CP.

The plurality of coupling parts CP and the plurality of spacers ACP are disposed between the first pad portion WL11 and the second pad portion WL12 of the printed circuit board PS and the plurality of pad portions PD of the semiconductor chip CHP as mentioned above, so that the distance D1 between the wiring layers WL of the printed circuit board PS and the semiconductor chip CHP may be relatively larger or may be increased as compared to the case where the plurality of coupling parts CP are disposed between the first pad portion WL11 and the second pad portion WL12 of the printed circuit board PS and the plurality of pad portions PD of the semiconductor chip CHP without the plurality of spacers ACP. For example, the distance D1 between the wiring layers WL of the printed circuit board PS and the semiconductor chip CHP may be larger or increased by the first thickness T1 of the plurality of spacers ACP. For example, a combined thickness of the first thickness T1 of the spacers ACP and the second thickness T2 of the coupling parts CP may separate the semiconductor chip CHP from the printed circuit board PS by the distance D1, where the distance D1 is more than 1 time but less than 3 times greater than the second thickness of the coupling part.

Accordingly, even if the size of the semiconductor chip CHP increases, the increased distance D1 (as provided by the thickness T1 of the spacers ACP) may reduce unnecessary or undesired parasitic capacitance which may occur between the plurality of wiring layers WL of the printed circuit board PS and the semiconductor chip CHP, so as to reduce or prevent degradation in performance of the semiconductor chip CHP due to unnecessary or undesired parasitic capacitance between the semiconductor chip CHP and the plurality of wiring layers WL of the printed circuit board PS.

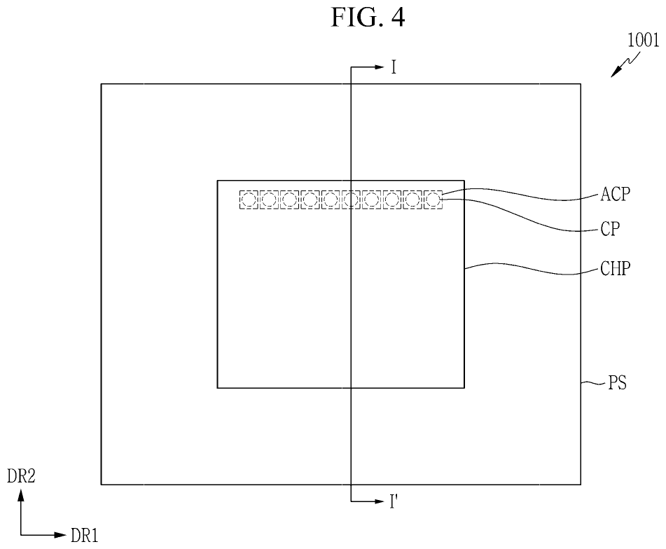

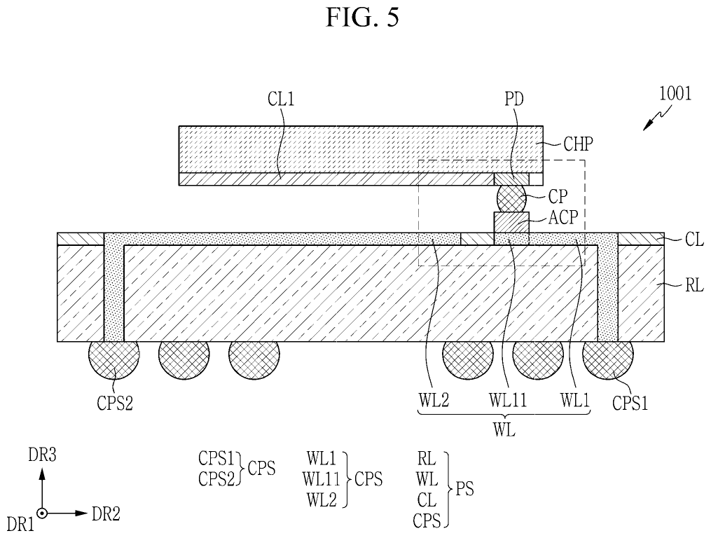

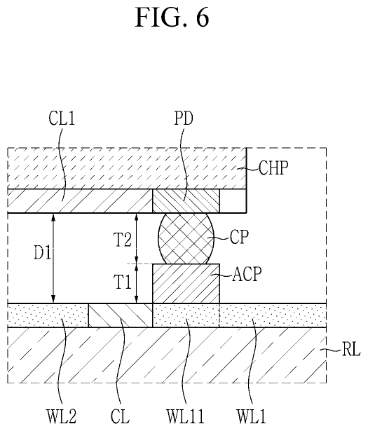

Now, with reference to FIG. 4 to FIG. 6, a semiconductor package according to another embodiment will be described. FIG. 4 is a plan view of a semiconductor package according to another embodiment, and FIG. 5 is a cross-sectional view taken along line I-I′ in FIG. 4, and FIG. 6 is an enlarged view of a portion of FIG. 5.

Referring to FIG. 4 to FIG. 6, a semiconductor package 1001 is similar to the semiconductor package 1000 according to the above-described embodiment. A detailed description of identical constituent elements will not be made.

Referring to FIG. 4, the semiconductor package 1001 according to another embodiment may include a printed circuit board PS, and a semiconductor chip CHP mounted on the printed circuit board PS.

Between the printed circuit board PS and the semiconductor chip CHP, a plurality of coupling parts CP and a plurality of spacers ACP. The semiconductor chip CHP may be coupled to the printed circuit board PS through the plurality of coupling parts CP and the plurality of spacers ACP.

The plurality of spacers ACP may overlap the plurality of coupling parts CP, respectively, in plan view.

The printed circuit board PS and the semiconductor chip CHP may extend along a first direction DR1 and a second direction DR2 different from each other.

Unlike the semiconductor package 1000 according to the above-described embodiment, according to the semiconductor package 1001 of the present embodiment, the plurality of coupling parts CP may be disposed adjacent to at least one edge of the semiconductor chip CHP in the second direction DR2, and the plurality of coupling parts CP may be disposed in a line or aligned along the first direction DR1.

The plurality of coupling parts CP is disposed in a line adjacent to one edge of the semiconductor chip CHP to increase or maximize available area of the chip CHP, so that main components of the semiconductor chip CHP may be disposed in most areas of the semiconductor chip CHP. The plurality of coupling parts CP is disposed adjacent to one edge of the semiconductor chip CHP as mentioned above, so that the distance between the plurality of coupling parts CP and main components of the semiconductor chip CHP disposed adjacent to another edge facing one edge to which the plurality of coupling parts CP is disposed to be adjacent may increase.

Referring to FIG. 5 together with FIG. 4, the printed circuit board PS may include an insulating layer RL, a plurality of wiring layers WL that is disposed on the insulating layer RL, a passivation layer CL that covers the insulating layer RL and the plurality of wiring layers WL of the printed circuit board PS to protect them, and a plurality of connection parts CPS that is coupled to the plurality of wiring layers WL.

The plurality of wiring layers WL may include a first wiring layer WL1 and a second wiring layer WL2, and the first wiring layer WL1 may include first pad portions WL11, and the second wiring layer WL2 may not be electrically coupled to the semiconductor chip CHP. The first pad portions WL11 may be end portions of the first wiring layer WL1. However, the embodiment is not limited thereto, and the plurality of wiring layers WL may include more wiring layers besides or in addition to the first wiring layer WL1 and the second wiring layer WL2.

The passivation layer CL may cover the insulating layer RL and the plurality of wiring layers WL of the printed circuit board PS to protect them, and passivation layer CL may not cover at least a portion of the plurality of wiring layers WL. For example, the first pad portions WL11 may not be covered by the passivation layer CL; however, the embodiment is not limited thereto.

Along a third direction DR3 perpendicular to the first direction DR1 and the second direction DR2 (also referred to as a vertical direction), the spacers ACP may be disposed on the first pad portions WL11, respectively, and the coupling parts CP may be disposed on the spacers ACP.

The plurality of spacers ACP may have conductivity. The plurality of spacers ACP may contain the same conductive material as that of the plurality of wiring layers WL. The plurality of spacers ACP may be portions of the same layer as that of the plurality of wiring layers WL.

The coupling parts CP may be coupled to pad portions PD of the semiconductor chip CHP. The pad portions PD of the semiconductor chip CHP may not be covered by a first passivation layer CL1 so as to be exposed, and be coupled to the coupling parts CP.

The plurality of connection parts CPS may include first connection parts CPS1 that are coupled to the first pad portions WL11, and a second connection part CPS2 that is coupled to the second wiring layer WL2.

Through the plurality of connection parts CPS, the printed circuit board PS may be coupled to an external device.

Referring to FIG. 6 together with FIG. 4 and FIG. 5, the plurality of coupling parts CP and the plurality of spacers ACP may be disposed between the printed circuit board PS and the semiconductor chip CHP.

The plurality of coupling parts CP and the plurality of spacers ACP may be disposed on the first pad portions WL11, and the plurality of spacers ACP may protrude from the first pad portions WL11 above the passivation layer CL in a direction away from the printed circuit board PS.

The first thickness T1 of the plurality of spacers ACP may be about 0.2 times to 1.7 times the second thickness T2 of the plurality of coupling parts CP, and in some embodiments may be about 0.4 times to about 1.5 times the second thickness T2. For example, the second thickness T2 of the plurality of coupling parts CP may be about 40 μm to about 50 μm, and the first thickness T1 of the plurality of spacers ACP may be about 20 μm to about 75 μm; however, the embodiment is not limited thereto.

Between the plurality of first pad portions WL11 of the printed circuit board PS and the plurality of pad portions PD of the semiconductor chip CHP, the plurality of spacers ACP may be further disposed besides or in addition to the plurality of coupling parts CP.

The plurality of coupling parts CP and the plurality of spacers ACP are disposed between the plurality of first pad portions WL11 of the printed circuit board PS and the plurality of pad portions PD of the semiconductor chip CHP as mentioned above, so that the distance D1 between the wiring layers WL of the printed circuit board PS and the semiconductor chip CHP may be relatively larger or increased as compared to the case where only the plurality of coupling parts CP is disposed between the plurality of first pad portions WL11 of the printed circuit board PS and the plurality of pad portions PD of the semiconductor chip CHP without the plurality of spacers ACP. For example, the distance D1 between the wiring layers WL of the printed circuit board PS and the semiconductor chip CHP may be larger by the first thickness T1 of the plurality of spacers ACP.

When the plurality of coupling parts CP is disposed adjacent to one edge of the semiconductor chip CHP as described above, the distance between the plurality of coupling parts CP and main components of the semiconductor chip CHP disposed adjacent to another edge facing one edge to which the plurality of coupling parts CP is disposed to be adjacent may increase. Accordingly, the overlapping area between the plurality of wiring layers WL of the semiconductor chip CHP and the printed circuit board PS may increase, and unnecessary or undesired parasitic capacitance that may occur between the plurality of wiring layers WL and the semiconductor chip CHP may also increase.

However, according to the present embodiment, the plurality of coupling parts CP and the plurality of spacers ACP are disposed between the plurality of first pad portions WL11 of the printed circuit board PS and the plurality of pad portions PD of the semiconductor chip CHP, whereby the distance D1 between the wiring layers WL of the printed circuit board PS and the semiconductor chip CHP may be relatively larger or increased (relative to the case where the plurality of spacers ACP are not present between the first pad portions WL11 and the pad portions PD).

Accordingly, even if the size of the semiconductor chip CHP (and in particular, the amount of overlap between the wiring layers WL of the chip CHP and the printed circuit board PS) increases, it is possible to reduce unnecessary or undesired parasitic capacitance which may occur between the plurality of wiring layers WL of the printed circuit board PS and the semiconductor chip CHP, and it is possible to reduce or prevent degradation in performance of the semiconductor chip CHP due to unnecessary or undesired parasitic capacitance between the semiconductor chip CHP and the plurality of wiring layers WL of the printed circuit board PS.

Many features of the semiconductor package 1000 according to the embodiment described above with reference to FIG. 1 to FIG. 3 are all applicable to the semiconductor package 1001 according to the present embodiment.

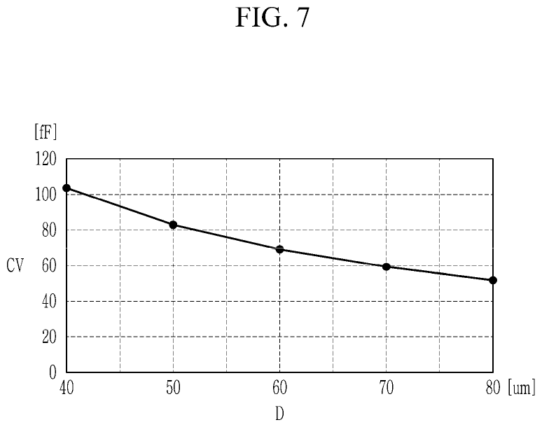

Now, with reference to FIG. 7, one experimental example will be described. FIG. 7 is a graph illustrating experimental results of an example embodiment, which may also be referred to as an experimental example.

In the present experimental example, as in the semiconductor packages 1000 and 1001 according to the embodiments, besides or in addition to a plurality of coupling parts, a plurality of spacers was disposed between a plurality of pad portions of a printed circuit board and a plurality of pad portions of a semiconductor chip, and parasitic capacitance CV between the semiconductor chip and a plurality of wiring layers of the circuit board were measured while changing the thickness D of the plurality of spacers, and the result is shown in FIG. 7. In the present experimental example, conditions other than the thickness D of the plurality of spacers were kept constant.

Referring to FIG. 7, it was found that as the thickness D of the plurality of spacers that is disposed between the plurality of pad portions of the printed circuit board and the plurality of pad portions of the semiconductor chip had increased, the parasitic capacitance CV between the semiconductor chip and the plurality of wiring layers of the printed circuit board had gradually decreased. This can be inferred or determined to be due to the increase in the distance D1 between the semiconductor chip and the plurality of wiring layers attributable to the increase in the thickness D of the plurality of spacers disposed between the plurality of pad portions of the printed circuit board and the plurality of pad portions of the semiconductor chip.

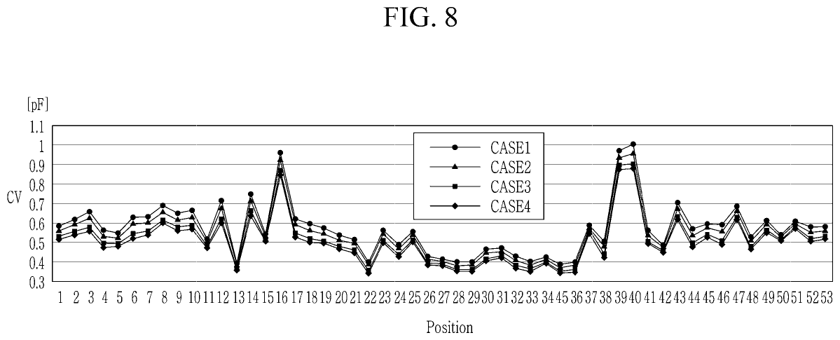

With reference to FIG. 8 and Table 1, the experimental results of another example embodiment will be described. FIG. 8 is a graph illustrating the result of another experimental example.

In the present experimental example, with respect to the case where only a plurality of coupling parts was disposed between a plurality of pad portions of a printed circuit board and a plurality of pad portions of a semiconductor chip (CASE 1), the case where besides or in addition to a plurality of coupling parts, a plurality of spacers was disposed between a plurality of pad portions of a printed circuit board and a plurality of pad portions of a semiconductor chip and the thickness of the plurality of spacers is about 20 μm (CASE 2), the case where the thickness of a plurality of spacers is about 40 μm (CASE 3), and the case where the thickness of a plurality of spacers is about 60 μm (CASE 4), the parasitic capacitance CV between the semiconductor chips and the printed circuit boards were measured while applying a signal to each semiconductor chip 53 times, and the result is shown in FIG. 8. Further, the rates of change of parasitic capacitance between the semiconductor chip and the printed circuit board in CASE 2, CASE 3, and CASE 4 with respect to CASE 1 were calculated, and are shown in Table 1.

TABLE 1

| Rate of Change (decrease) | | | |
|---|---|---|---|
| of Parasitic Capacitance | CASE 2 | CASE 3 | CASE 4 |
| Maximum | 3.1% | 5.8% | 6.3% |
| Minimum | 6.7% | 13.8% | 17.7% |
| Average | 5.2% | 9.9% | 12.5% |

Referring to FIG. 8, it can be seen that the parasitic capacitance between the semiconductor chips and the printed circuit boards in CASE 2, CASE 3, and CASE 4 had all decreased as compared to CASE 1.

Referring to Table 1, it can be seen that the degree of increase in the rate of decrease of parasitic capacitance between the semiconductor chip and the circuit board in CASE 3 with respect to CASE 2 was greater than the degree of increase in the rate of decrease of parasitic capacitance between the semiconductor chip and the circuit board in CASE 4 with respect to CASE 3.

As described above, according to the semiconductor packages 1000 and 1001 of the embodiments, it can be seen that when not only the plurality of coupling parts CP but also the plurality of spacers ACP may be disposed between the plurality of pad portions WL11 and WL12 of the printed circuit boards PS and the plurality of pad portions PD of the semiconductor chips CHP, it is possible to reduce unnecessary or undesired parasitic capacitance which may occur between the plurality of wiring layers WL of the printed circuit board PS and the semiconductor chip CHP, and it is possible to reduce or prevent degradation in performance of the semiconductor chip CHP due to unnecessary or undesired parasitic capacitance between the semiconductor chip CHP and the plurality of wiring layers WL of the printed circuit board PS.

While this disclosure has been described in connection with what is presently considered to be practical embodiments, it is to be understood that the invention is not limited to the disclosed embodiments. On the contrary, it is intended to cover various modifications and equivalent arrangements included within the scope of the appended claims.

What is claimed is:

1. A semiconductor package comprising:
a printed circuit board comprising a first pad portion;
a semiconductor chip that is mounted on the printed circuit board and comprises a second pad portion;
a coupling part that is between the first pad portion and the second pad portion; and
a spacer that is between the coupling part and the first pad portion,
wherein the first pad portion and the second pad portion are electrically coupled to each other through the coupling part and the spacer.

2. The semiconductor package of claim 1, wherein
the first pad portion and the spacer comprise the same conductive material.

3. The semiconductor package of claim 2, wherein
the first pad portion and the spacer comprise portions of a same layer.

4. The semiconductor package of claim 3, wherein
the spacer protrudes from the first pad portion toward the semiconductor chip.

5. The semiconductor package of claim 4, wherein
the semiconductor chip extends in a first direction and a second direction different from the first direction,
the coupling part and the spacer are included among a plurality of coupling parts and a plurality of spacers, respectively, that are arranged along a direction parallel with the first direction, and
the plurality of coupling parts and the plurality of spacers are provided at a central region of the semiconductor chip in the second direction.

6. The semiconductor package of claim 5, wherein
a first thickness of the spacer is about 0.2 times to about 1.7 times a second thickness of the coupling part.

7. The semiconductor package of claim 6, wherein
the first thickness of the spacer is about 0.4 times to about 1.5 times the second thickness of the coupling part.

8. The semiconductor package of claim 4, wherein
the semiconductor chip extends in a first direction and a second direction different from the first direction,
the coupling part and the spacer are included among a plurality of coupling parts and a plurality of spacers, respectively, that are arranged along a direction parallel with the first direction, and
the plurality of coupling parts and the plurality of spacers are adjacent to an edge of the semiconductor chip in the second direction.

9. The semiconductor package of claim 8, wherein
a first thickness of the spacer is about 0.2 times to about 1.7 times a second thickness of the coupling part.

10. The semiconductor package of claim 9, wherein
the first thickness of the spacer is about 0.4 times to about 1.5 times the second thickness of the coupling part.

11. The semiconductor package of claim 4, wherein
the printed circuit board further comprises a passivation layer,
the first pad portion is exposed by the passivation layer, and
the spacer protrudes away from a surface of the passivation layer toward the semiconductor chip.

12. The semiconductor package of claim 11, wherein
a thickness of the first pad portion is substantially equal to a thickness of the passivation layer, or is smaller than the thickness of the passivation layer.

13. The semiconductor package of claim 12, wherein
the passivation layer comprises a resin.

14. The semiconductor package of claim 4, wherein
a first thickness of the spacer is about 0.2 times to about 1.7 times a second thickness of the coupling part.

15. The semiconductor package of claim 14, wherein
the first thickness of the spacer is about 0.4 times to about 1.5 times the second thickness of the coupling part.

16. The semiconductor package of claim 1, wherein
the printed circuit board further comprises a passivation layer,
the first pad portion is exposed by the passivation layer, and
the spacer protrudes away from a surface of the passivation layer toward the semiconductor chip.

17. The semiconductor package of claim 16, wherein
a thickness of the first pad portion is substantially equal to a thickness of the passivation layer, or is smaller than the thickness of the passivation layer.

18. The semiconductor package of claim 17, wherein
the passivation layer comprises a resin.

19. The semiconductor package of claim 1, wherein
a first thickness of the spacer is about 0.2 times to about 1.7 times a second thickness of the coupling part.

20. The semiconductor package of claim 19, wherein
the first thickness of the spacer about 0.4 times to about 1.5 times the second thickness of the coupling part.
